(19) United States
(12) Patent Application Publication
(10) Pub. No.: US 2025/0199039 A1
(43) Pub. Date: Jun. 19, 2025

(54) METHOD AND SYSTEM FOR OPERATING MODE DETECTION OF OVERLAPPING LOADS

(71) Applicant: EATON INTELLIGENT POWER LIMITED, Dublin 4 (IE)

(72) Inventors: Mayura, Arun MADANE, Pune (IN); Prachi, Suresh ZAMBARE, Pune (IN); Niall CAHILL, Dublin (IE)

(21) Appl. No.: 18/849,689

(22) PCT Filed: Jun. 10, 2022
(86) PCT No.: PCT/EP2022/025270

§ 371 Date: Sep. 23, 2024

(30) Foreign Application Priority Data
Mar. 24, 2022 (IN) 202211016702

(51) Int. Cl. G01R 19/25; H02J 13/00

(52) U.S. Cl. CPC G01R 19/25; H02J 13/00002

(57) ABSTRACT

Some embodiments relate to an overlapping electric loads operating mode detection method. The method includes measuring an aggregated power signal of an electrical outlet and determining an operating mode for the aggregated power signal. The operating mode is determined to be one of an active mode, a lower power mode, or switched off. On determining the operating mode is an active mode, the method includes determining a load category for the aggregated power signal; selecting a corresponding load category signature power signal from a load category database; evaluating spectral coherence between the aggregated power signal and the load category signature power signal; determining an overall probability of coherence between frequency components of the aggregated power signal and the load category signature power signal; determining if a low power mode is present within the active mode aggregated power signal; and determining the operating modes of each of the overlapping electric loads.

### CROSS-REFERENCE TO RELATED APPLICATIONS

This application is a national phase filing under 35 C.F.R. § 371 of and claims priority to PCT Patent Application No. PCT/EP2022/025270, filed on Jun. 10, 2022, which claims the priority benefit under 35 U.S.C. § 119 of Indian Patent Application number 202211016702, filed on Mar. 24, 2022, the contents of which are hereby incorporated in their entireties by reference

### FIELD OF DISCLOSURE

The field of this disclosure relates to determining operating modes for multiple overlapping electrical loads. In particular, a method and system for determining low power modes within an aggregated higher power signal.

### BACKGROUND

The monitoring of all power consumption of electric loads associated with power management systems is often overlooked. In particular, for energy management purposes, it is common that only the high power electric loads are assessed, and for an electric circuit where there is only one load connected. Therefore, only a single operating mode is determined. However, in an electrical circuit fed from circuit breakers or power strips, there can be multiple electrical loads which are supplied from single outlet or circuit breaker. These multiple electrical loads which are connected to the same circuit can be operating with different operating modes at the same time. The resultant electrical signal at the circuit breaker or power strip will therefore comprise an aggregated electrical signal of overlapping loads with different electrical power when operating in different modes. As such, some of the loads can be in active mode (i.e. performing actual operation) and some of the loads can be in low power mode (i.e. standby mode).

For example, electric loads and/or appliances used in a building go through various operating modes depending on the actual work being done by the load, which can also be dependent on the usage by the user. For example, a microwave when being actively used for heating can be classified as being in active mode, whereas when it is plugged in to the electric outlet and not used for heating it can be classified as being in standby mode or low power mode. Through existing approaches, it is possible to detect operating modes for an outlet/load when a load is individually powered or singly operated (U.S. Pat. No. 10,837,989, 2020). But, as with the microwave example, with a circuit breaker having multiple kitchen appliances connected, not all loads would be powered at the same time.

In order to provide more accurate energy saving recommendations or power control to end users it is advantageous to know if any of the loads of the combined electrical signal are operating in a low power mode. Providing a detailed analysis of the varying operating modes from loads of an aggregated signal, in particular low power mode, allows for further energy saving opportunities for the end user. On determining the low power operating mode loads, the user can opt to turn these loads off, thus saving power and energy.

### SUMMARY

The presently disclosed subject matter provides a method to detect the presence of a low power operating mode in the case of overlapping loads. By effectively detecting the operating mode of the appliance, various benefits can be provided. It provides customers the visibility of the load energy/power usage by operating modes. In a networked plug-in load system, this information is particularly important to provide the aggregate energy/power consumption with a differentiation/segmentation between the energy that is really in use, and the energy that is thought to be consumed by the user. This information provides a direct visibility to the potential saving opportunities to customers.

Further, a reliable operating mode detection also ensures reliable control (or a safe turn-OFF) of plug-in critical loads, with minimized potential damage to the devices and negative impacts to users. Thus, it helps to minimize the unnecessary nuisance trip when the plugged-in loads, especially critical loads, are to be turned-off.

In an aspect of the disclosure there is provided an overlapping electric loads operating mode detection method, the overlapping electric loads operating mode detection method comprising: measuring an aggregated power signal of an electrical outlet; determining an operating mode for the aggregated power signal, wherein the operating mode is determined to be one of an active mode, a lower power mode, or switched off; on determining the operating mode is active mode, the method further comprising: determining a load category for the aggregated power signal; selecting a corresponding load category signature power signal from a load category database; evaluating spectral coherence between the aggregated power signal and the load category signature power signal; determining an overall probability of coherence between frequency components of the aggregated power signal and the load category signature power signal; determining if a low power mode is present within the active mode aggregated power signal, whereby a low power mode is arranged to be detectable based on the probability of coherence value; and determining the operating modes of each of the overlapping electric loads.

Knowing the operating modes of overlapping electric loads improves power consumption monitoring and provides enhanced energy management capabilities, including effective control of loads.

In some embodiments, measuring the aggregated power signal may comprise reading the aggregated current and voltage signals of the electrical outlet. Measuring from the electrical outlet allows for monitoring and acquisition to be performed at a single source rather than at each load. This is also advantageous if certain locations have restricted access.

In some embodiments, the reading of the aggregated current and voltage signals may be performed for a minimum of 5 cycles. Acquiring the signal for a minimum of 5 cycles allows for any anomalies or abnormalities that are induced in a cycle to be minimised in the resultant measured aggregated signal.

In some embodiments, the load category of the aggregated power signal may be determined to be one of a plurality of load categories, the load categories may comprise: Power Electronic Load without Power Factor Correction (NP); Power Electronic Load with Power Factor Correction (P); Transformer (T); Reactive (X); Phase Angle controlled (PAC); Complex (M); or Resistive (R). Knowing the load category aids in determining the appliance associated with the load, such that the power management of such appliance can be controlled. It will be realised by a skilled person in the art that other load categories can be used and the method is not limited to the aforementioned load categories.

In some embodiments, the method may further comprise normalising the aggregated power signal, wherein the aggregated current and voltage waveform is normalised. Normalising the aggregated signal allows for easier comparison with a normalised sample signal, as it is the behaviour of the waveform and not the maximum current or voltage that is of interest.

In some embodiments, the load category signature power signals may comprise one cycle active mode normalised waveform for each load category. The load category signature power signal is a sample signal which has been calibrated for a particular load category, thus only requires a single cycle when the particular load is operating in active mode.

In some embodiments, evaluating spectral coherence between the aggregated power signal and the load category signature power signal may further comprise: evaluating the difference between the aggregated power signal and the load category signature power signal based on their respective voltage/current, VI, trajectory waveforms and area enclosed in the VI trajectories.

In some embodiments, evaluating spectral coherence between the aggregated power signal and the load category signature power signal may further comprise: calculating the difference between the VI trajectory enclosed areas of the aggregated power signal and the load category signature power signal using root mean square error (RMSE) analysis. The difference in the area enclosed by the VI trajectories of the aggregated power signal and the load category signature power (sample) signal is used as a distinguishing feature, as this distinguishing feature aids in providing an easier and more accurate prediction of a low power load being present in the aggregated signal.

In some embodiments, evaluating spectral coherence between the aggregated power signal and the load category signature power signal may further comprise: estimating spectral coherence between a normalised current signal of aggregated power signal and a normalised current signal of the load category signature power signal using Welch's averaged modified periodogram method (https://en.wikipedia.org/wiki/Welch%27s_method). Again, this is a distinguishing feature which aids in providing an easier and more accurate prediction of a low power load being present in the aggregated signal.

In some embodiments, evaluating spectral coherence between the aggregated power signal and the load category signature power signal may further comprise: recording the spectral coherence estimates for all frequency components of the compared signals.

In some embodiments, the method may further comprise evaluating the spectral correlation count between the aggregated power signal and the load category signature power signal, wherein evaluating the spectral correlation count comprises counting the number of frequency components where the coherence value is below a threshold.

In some embodiments, the coherence value may be below a threshold of 0.8. Having a reasonable threshold value, such as 0.8, allows for any outliers in the spectral correlation count that may be close to a 1 to 1 correlation to be ruled out, as having a 1 to 1 correlation means there is no difference between the frequency components of the compared signals.

In some embodiments, the method may further comprise evaluating the phase difference between the aggregated power signal and the load category signature power signal at 120 Hz frequency. Again, this is a distinguishing feature which aids in providing an easier and more accurate prediction of a low power load being present in the aggregated signal.

In some embodiments, the method may further comprise calculating the overall probability using a sigmoid membership function for each feature, wherein the features comprise the VI waveform area difference, the spectral correlation count and the phase difference of the aggregated power signal and the load category signature power signal.

In some embodiments, the sigmoidal membership function may be given by the equation:

$$f ( x ) = \frac{1}{1 + {e}^{\frac{- ( x - α )}{β}}}$$

wherein α is the centre point of the distribution and β is the width of the distribution.

In some embodiments, the overall probability of coherence may be calculated using the following equation:

$$Prob = Phase 120 \times DiffArea \times SpectralCorr$$

wherein Phase120 is the membership function of the phase difference at 120 Hz, DiffArea is the membership function of the VI waveform area difference, and SpectralCorr is the membership function of the spectral correlation count.

In some embodiments, a low power mode may be present when the probability of coherence value is greater than 0.5.

In some embodiments, the frequency components may include AC and DC. Measuring the frequency components of both AC and DC covers all different types of loads using the single method.

In some embodiments, the number of frequency components may be greater than >1.

In an aspect of the disclosure there is provided an operating mode detection system of overlapping electric loads, the operating mode detection system comprising: an electrical outlet; an external computing component, wherein the external computing component is configured to: measure, via the electrical outlet, an aggregated power signal; determine an operating mode for the aggregated power signal, wherein the operating mode is determined to be one of an active mode, a lower power mode, or switched off; when the operating mode is determined to be active mode the external computing component is further configured to: determine a load category for the aggregated power signal; select a corresponding load category signature power signal from a load category database; evaluate spectral coherence between the aggregated power signal and the load category signature power signal; determine an overall probability of coherence between frequency components of the aggregated power signal and the load category signature power signal; determine if a low power mode is present within the active mode aggregated signal based on the determined probability of coherence value; and determine the operating modes of each of the overlapping loads.

### BRIEF DESCRIPTION OF THE DRAWINGS

The disclosure will be described, by way of example only, with reference to the accompanying drawings, in which:

FIG. 1 is a schematic diagram of the system components;

FIG. 2 is a flow diagram of the method steps for determining the operating mode of overlapping and non-overlapping loads;

FIG. 3 illustrates a plot of real power and a plot of mode ID for a number of cycles for a load in active mode;

FIG. 4a-c illustrate plots of real power and plots of mode ID for a number of cycles for 3 different loads in low power mode;

FIG. 5 illustrates a plot of combined real power and a plot of combined mode ID for a number of cycles for 4 different loads in active and low power modes;

FIG. 6 is a plot of aggregated current for 4 different loads combined and the current for the individual loads, one in active mode and 3 in low power mode;

FIG. 7a illustrates the voltage/current, VI, trajectory for 4 different loads, wherein all loads are in low power mode;

FIG. 7b illustrates the aggregated VI trajectory for the 4 different loads of FIG. 7a;

FIG. 8a illustrates the VI trajectory for 4 different loads, wherein one load is in active mode and the others are in low power mode;

FIG. 8b illustrates the aggregated VI trajectory for the 4 different loads of FIG. 8a;

FIG. 9a illustrates the VI trajectory for 4 different loads, wherein one load is in low power mode and the others are in active mode;

FIG. 9b illustrates the aggregated VI trajectory for the 4 different loads of FIG. 9a;

FIG. 10a illustrates the VI trajectory for 4 different loads, wherein all loads are in active mode;

FIG. 10b illustrates the aggregated VI trajectory for the 4 different loads of FIG. 10a;

FIG. 11 shows plots of example VI trajectories for different load categories;

FIG. 12a illustrates an area distribution plot when lower power is present in an aggregated current;

FIG. 12b illustrates an area distribution plot when lower power is absent in an aggregated current;

FIG. 13a shows normalised plots comparing a sample signal and aggregated signals of current, power and VI trajectory wherein all loads are in low power mode;

FIG. 13b is a coherence spectrum of current when all loads are in low power mode;

FIG. 14a shows normalised plots comparing a sample signal and aggregated signals of current, power and VI trajectory wherein one load is in active mode and the other loads are in low power mode;

FIG. 14b is a coherence spectrum of current when one load is in active mode and the other loads are in low power mode;

FIG. 15a shows normalised plots comparing a sample signal and aggregated signals of current, power and VI trajectory wherein one load is in low power mode and the other loads are in active mode;

FIG. 15b is a coherence spectrum of current when one load is in low power mode and the other loads are in active mode;

FIG. 16a shows normalised plots comparing a sample signal and aggregated signals of current, power and VI trajectory wherein all loads are in active mode;

FIG. 16b is a coherence spectrum of current when all loads are in active mode;

FIG. 17a illustrates spectral correlation count plots when lower power is present in an aggregated current;

FIG. 17b illustrates spectral correlation count plots when lower power is absent in an aggregated current;

FIG. 18a illustrates phase difference at 120 Hz frequency component plots when lower power is present in an aggregated current;

FIG. 18b illustrates phase difference at 120 Hz frequency component plots when lower power is absent in an aggregated current;

FIG. 19 shows a sigmoid function plot for a membership function for determining the overall probability of coherence.

### DETAILED DESCRIPTION

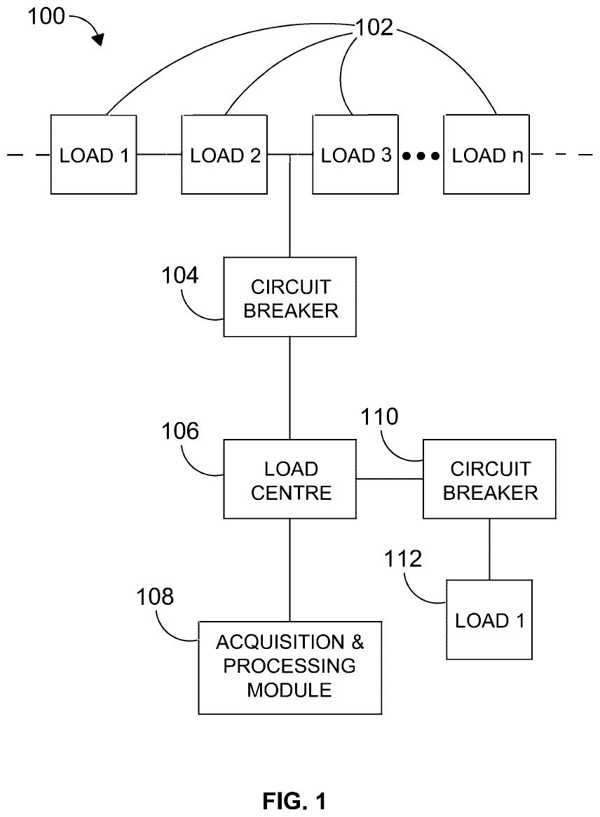

FIG. 1 is a schematic diagram illustrating the components of the operating mode detection system 100. As shown in FIG. 1, there are multiple loads 102 connected to a single circuit breaker 104, i.e. the loads have a shared circuit. As such, a single load does not have a dedicated circuit, i.e. one load 112 to one circuit breaker 110. It will be realised that a plurality of loads 102 can be connected to a single circuit breaker 104, and that the operating mode detection method can be utilised on a system containing one or more loads 102. The circuit breaker 104/110 may be a smart circuit breaker, an energy management circuit breaker (EMCB) or the like. The system can extend to a large scale building power management system where a combination of dedicated and non-dedicated circuits are present, and connected to a load centre 106. The system 100 also comprises an acquisition and processing module 108 for acquiring and processing the electrical and power signals from the circuit breaker 104/110. The acquisition and processing module 108 may be any suitable computing device or a multiple of computing devices which is operable to acquire electrical signals and process the data according to the operating mode detection method.

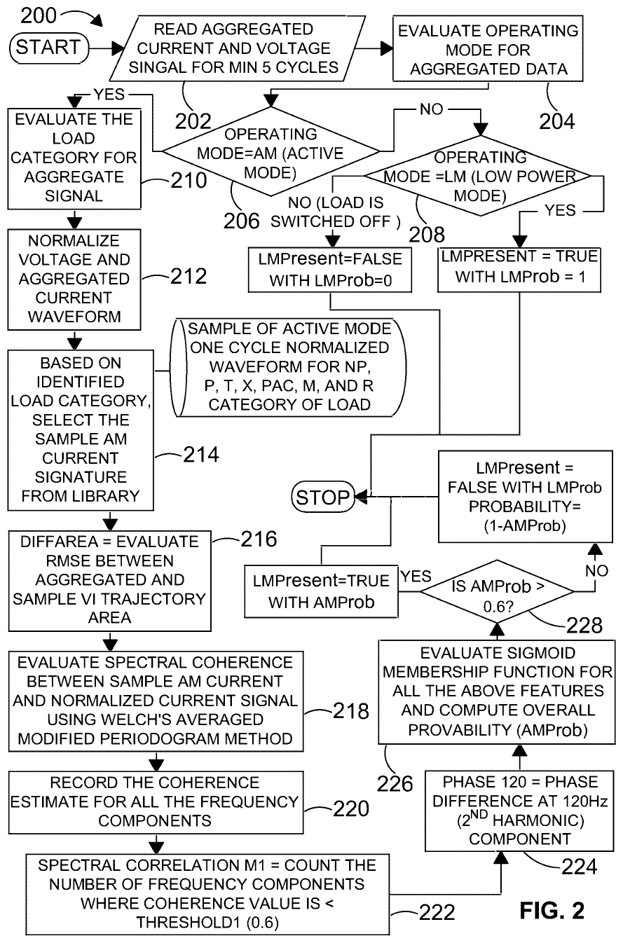

FIG. 2 is a flow diagram 200 of the method steps for determining the operating mode of overlapping and non-overlapping loads. In particular, a method for detecting low power operating mode loads in real time with overlapping load conditions. As shown in the flow diagram 200 of FIG. 2 the method starts by reading the aggregated power signal, i.e. measuring the aggregated current and voltage signal, for a minimum of 5 cycles 202 at the electrical outlet or circuit breaker. This is performed in real time by the acquisition and processing module 108 of the system of FIG. 1. A minimum of 5 cycles is required to obtain an accurate reading.

Once the aggregated signal is acquired the system evaluates the operating mode for the aggregated signal 204 by determining if the operating mode is an active mode, a low power mode or switched off. The existing method as disclosed in U.S. Pat. No. 10,837,989 is used to compute the overall operating mode of the aggregated signal. If all the loads connected to an outlet are in low power mode then aggregated mode is detected as low power mode. Therefore, the reverse is also true, in that if the aggregated mode is detected as low power mode then it is deduced that all of the connected loads are in low power mode. Similarly, if the aggregated current signal is zero, i.e. no signal is read, then all the loads are switched off. In evaluating the operating mode the method 200 determines from the aggregated data if the operating mode is an active mode 206. If no active mode is found, the method 200 then determines if a low power operating mode is present or not 208. Therefore, concluding that there is low power mode present on the one or more loads, or all the loads are switched off.

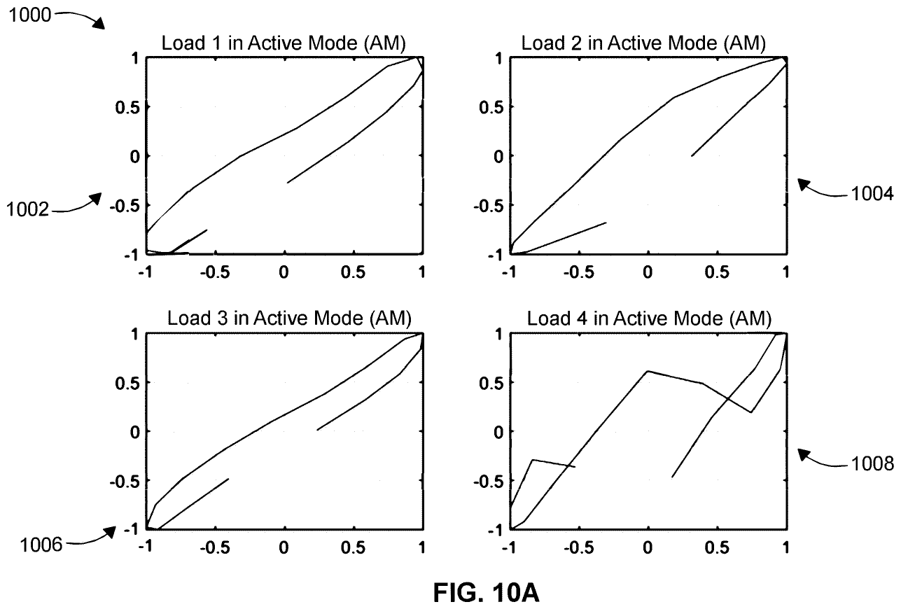

If it is determined that the operating mode of the aggregated signal is active mode 206 then it is possible that there are low power mode loads connected along with active power loads. Thus, further processing is required to classify presence of the low power mode loads within the aggregated active mode signal. Firstly, the load category for the aggregated signal is determined 210. The load can be characterised into various load categories including, resistive (R), inductive (X), power electronic with power factor correction (P), power electronic load without power factor correction (NP), microwave or complex loads (M), transformer (T), phase angle controlled loads (PAC). The voltage/current (VI) trajectory waveforms vary depending on the load category, thus evaluating the VI trajectory of the aggregated signal will help to identify the dominant load category of the aggregated signal. The details of the VI trajectories of the various load categories is discussed further in relation to FIG. 11. Once the load category is determined 210 the voltage and aggregate current waveform of the aggregated signal is normalised 212. Normalising the aggregated current and voltage waveform between −1 to 1 allows different loads of varying power levels to be assessed and compared. Then based on the identified load category the normalised signal is compared with a sample waveform of such a category as in step 214 of the method flow diagram 200. The sample waveform is selected from a library or database of current signatures for each if the different load categories 214. The sample waveform is an active mode, one cycle, normalised waveform for the particular category of load chosen.

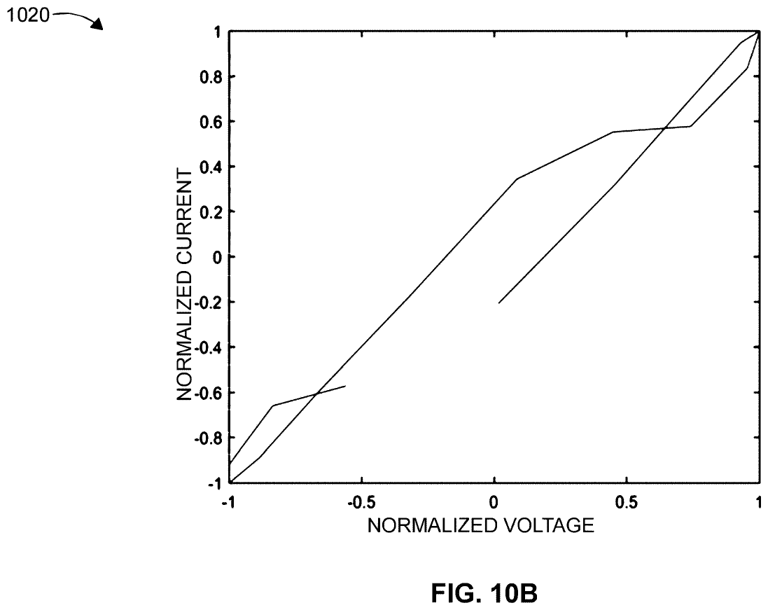

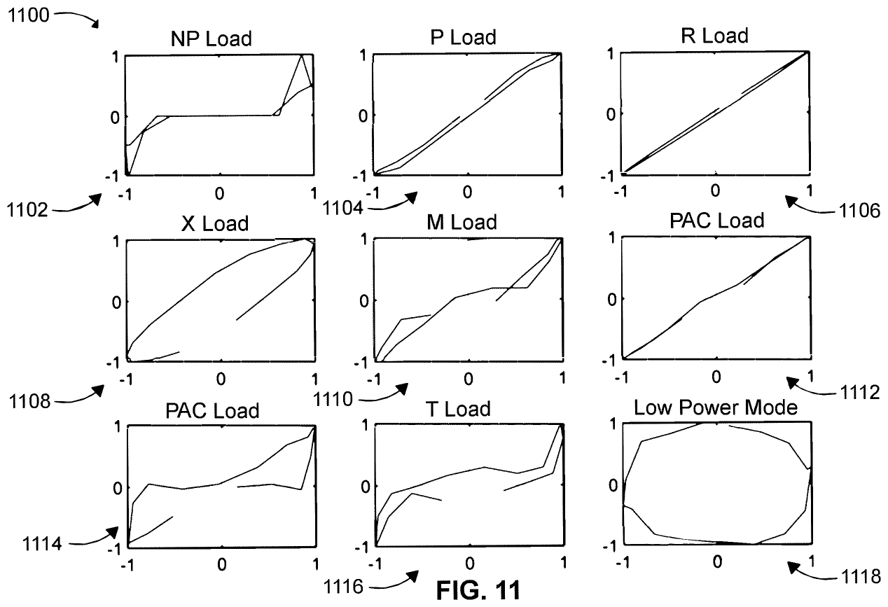

The next steps, 216 to 228, are implemented in order to extrapolate the low power mode signal(s) from the aggregated signal by evaluating the various differentiating features between the aggregated signal and the sample waveform from 214. In step 216, the distinguishing feature assessed is the difference in area in the enclosed VI trajectories of the aggregated signal and the sample signal. It is noted that there are differences in the VI trajectory for a given load category of an individual load when compared with an aggregated load. Therefore, using root mean square error (RMSE) to determine the difference between the enclosed areas of the VI trajectories provides an indication that a low power mode is present within the aggregated signal. Further details on determining the area difference 216 is provided below in relation to FIG. 12a and FIG. 12b.

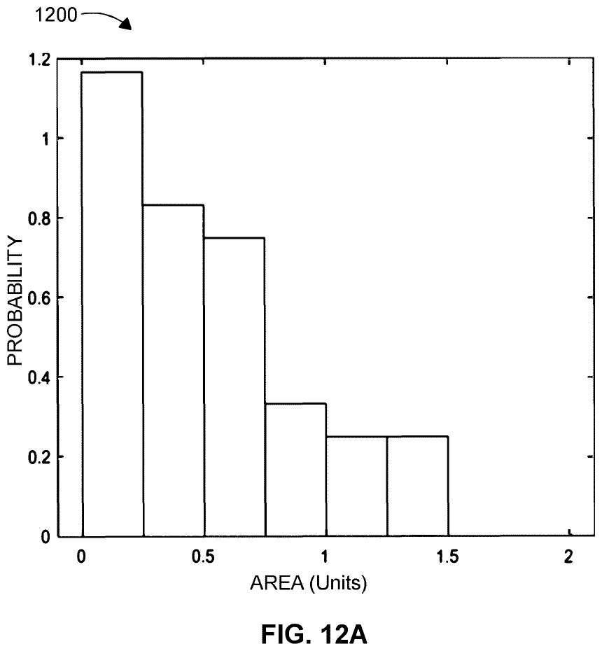

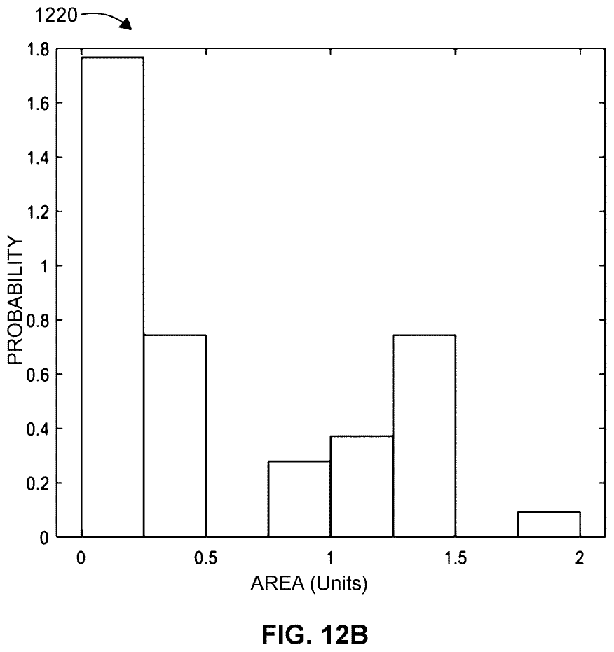

The next differentiating feature evaluated is the spectral coherence between the sample waveform and the aggregated waveform 218. In particular, the spectral coherence 218 is performed between the sample current of the sample signal and the aggregated current of the aggregated signal, both of which have been previously normalised. The spectral coherence 218 is determined by using Welch's averaged modified periodogram method. The spectral coherence indicates the correlation between various frequency components as well as their respective phase angles. The spectral coherence is found to be higher for majority of frequency components when the load current comprises all active mode loads, whereas the correlation decreases when the load current comprises a mix of low power mode loads and active mode loads. Therefore, a decreased correlation is an indicator that loads operating low power mode are present in the aggregated signal. The coherence estimates for all the frequency components of the signals are then recorded 220 and the number of frequency components where the coherence value is less than a threshold is calculated 222. The coherence value is preferably below a threshold of 0.8, and more preferably below a threshold of 0.6. Further details on the evaluation of spectral coherence is discussed in relation to FIGS. 13a to 17b.

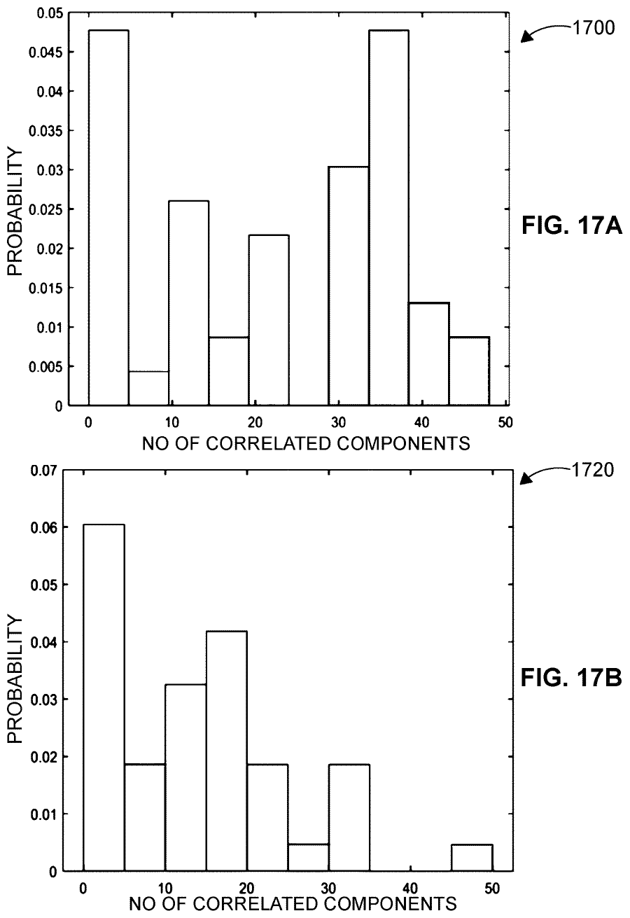

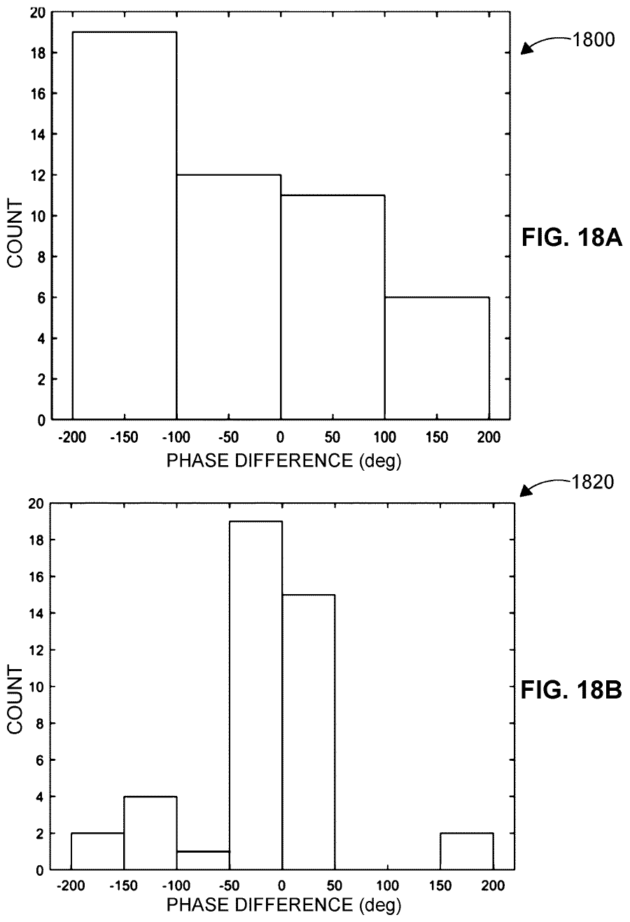

Once the spectral coherence is determined the next step of the method 200 is to determine the distinguishing feature of the phase difference between the aggregated signal and the sample signal 224. The phase difference is assessed at the 120 Hz component, i.e. at the second harmonic. The phase difference at 120 Hz is found to be higher over a larger range of phase differences (−200 to 200 degrees) when there is one or more low power mode loads present. Therefore, an increased distribution of phase differences at 120 Hz is an indicator that low power operating mode loads are present in the aggregated signal. More details are provided in relation to the phase difference below in conjunction with FIGS. 18a and 18b.

Once the differences of the distinguishing features are determined, as in steps 216 to 224, the method 200 then continues by determining the overall probability that one or more loads are operating in low power mode 226. A sigmoid membership function is used to determine if low power operating mode loads are present in the aggregated signal by inputting the data from the differentiating features into the sigmoidal function. If the overall probability is found to be greater than 0.5 then there is low power mode present in the aggregated signal 228. However, if the overall probability is less than 0.5 then there is no low power mode present and the aggregated signal comprises all active mode loads. It will be realised that the probability threshold may be a value greater than 0.5, for example 0.6, 0.7, 0.8, etc., depending on the level of accuracy required.

In combination with the method 200 of FIG. 2, further details are provided for each of the steps in determining the various factors required in order to determine the presence of low power operating mode loads in an aggregated signal.

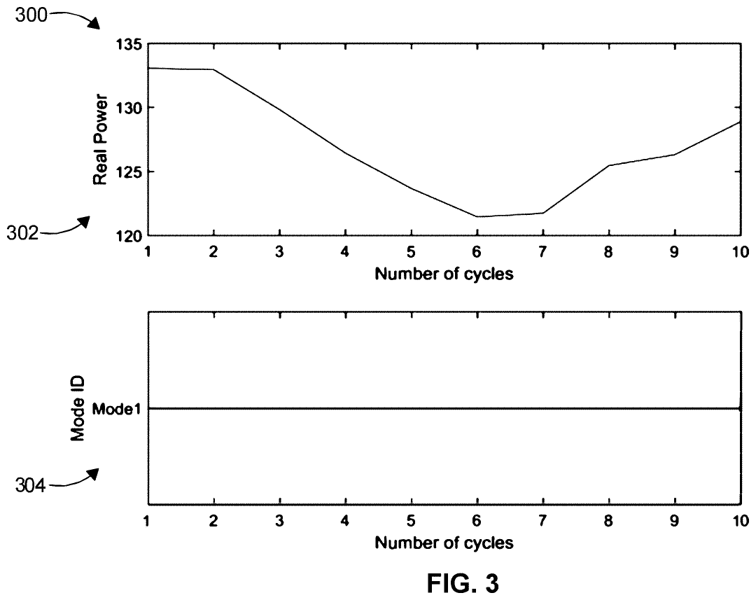

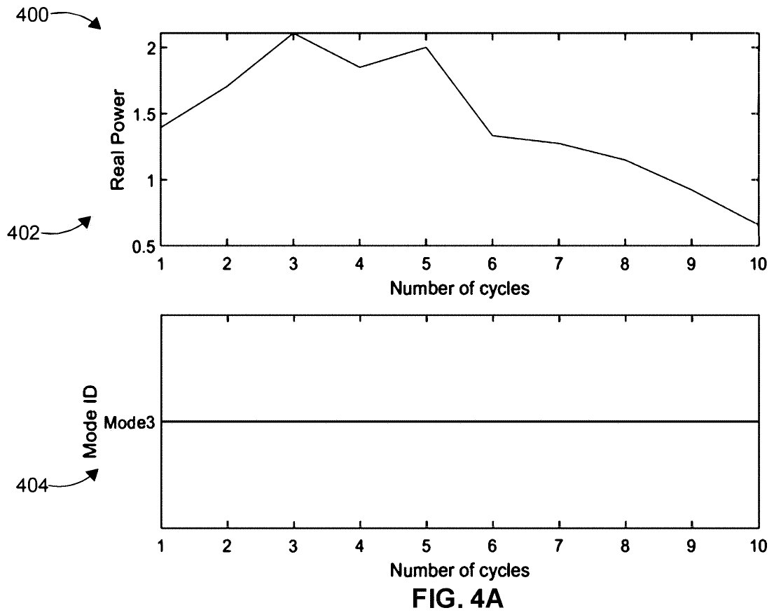

FIGS. 3 and 4a-c illustrate plots 300/400/420/440 of real power and mode ID for a number of cycles for various loads of varying operating mode. FIG. 3 represents the behaviour of a load when operating in active mode. As shown in 300 by the real power plot 302, the power signature over the 10 cycles is characteristic of a sine wave, i.e. an AC signal, with the power between approximately 120-135 W. Further, the mode, classified as mode 1, does not change throughout the duration of the cycles as shown in plot 304 of FIG. 3. FIGS. 4a-c represent the behaviour of different loads of various household appliances and devices when put in standby mode or sleep, i.e. operating in low power mode. It is clear from the real power plots 402, 422 and 442 of FIGS. 4a-c that the power values have reduced when compared with 302 of FIG. 3. The variation in power values across plots 402, 422 and 442 of FIGS. 4a-c is due to the different appliances/devices drawing different currents when in standby mode. However, plots 402, 422 and 442 of FIGS. 4a-c have similar characteristic power waveforms over the 10 cycle duration, wherein the power starts high and then drops on going from cycle 1 to cycle 10. These waveforms differ to that of 302 of FIG. 3. Further, the mode, classified as mode 3, does not change for each of the mode plots 404/424/444 in FIGS. 4a-c.

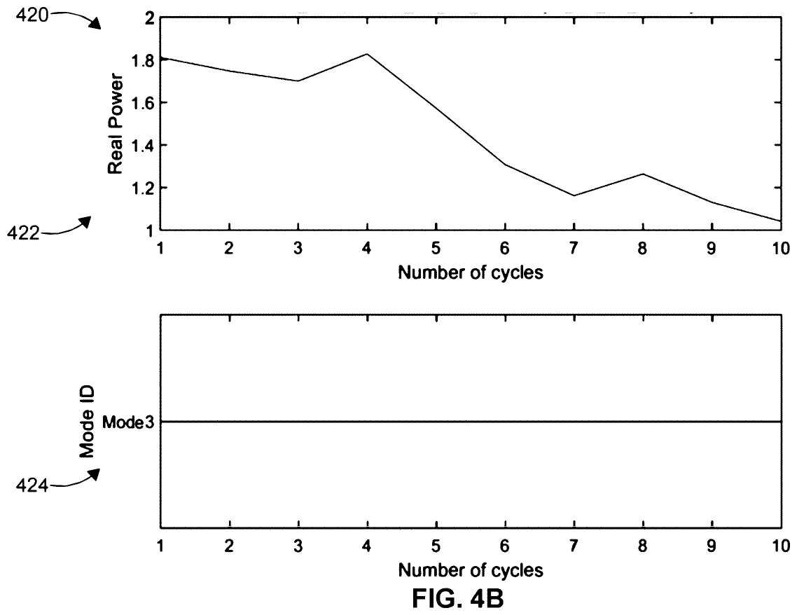

FIG. 5 illustrates the real power plot 502 and mode ID plot 504 over 10 cycles for an aggregated power signal comprising a mix of active and low power operating modes. It is clear that the power signature of 502 is comparable with the active mode power signature 302 of FIG. 3, i.e. characteristic AC sine wave. Further, the mode ID in 504 for the aggregated signal is classified as mode 1, i.e. active mode, as was also in 304 of FIG. 3. Therefore, measuring the power over a number of cycles for an aggregated signal from a plurality of loads on the same circuit would not provide any insight into whether low operating modes exist on any of the loads as the high power load dominates the overlapping loads. Thus, this approach cannot differentiate if any of the loads are in low power mode, and as such further analysis is required as outlined by the method steps 200 of FIG. 2. This is also true for loads which transition from active mode to low power mode in an overlapping load circuit where multiple loads are in active mode. The transition can go unnoticed as the high power load(s) which remains ON will dominate the aggregated signal due to the power change of the transition being very small. Thus, the switch from active mode to low power mode of one of the loads goes undetected. Hence, the method 200 as outlined in FIG. 2 is performed in real time to detect real time load behaviours.

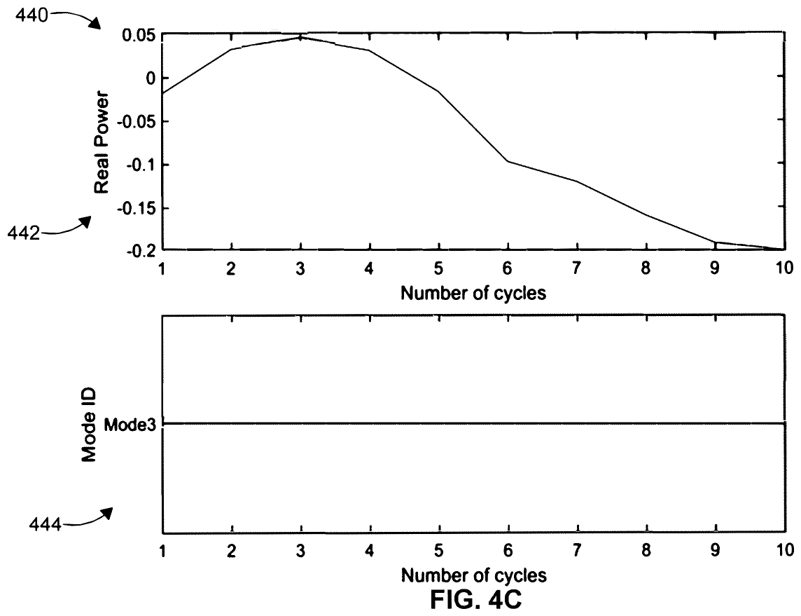

FIG. 6 is a plot 600 of aggregated current for 4 different loads combined 606 along with the current for each of the individual loads 602/604 for 200 samples, wherein the loads are arranged such that one is in active mode 602 and 3 are in low power mode 604. It is clear from the measured current signals of 600 that the aggregated current 606 or the current of the combined loads of 602 and 604 is comparable with the current of the load in active mode (AM) 602. Thus, similar to the real power measurements in FIGS. 3 and 4a-c, the aggregated current pattern is dominated by the high power load.

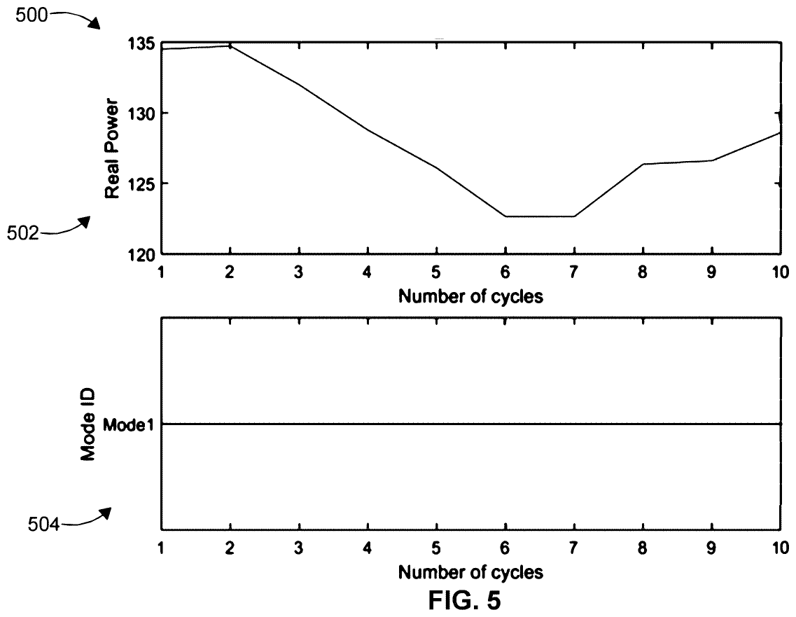

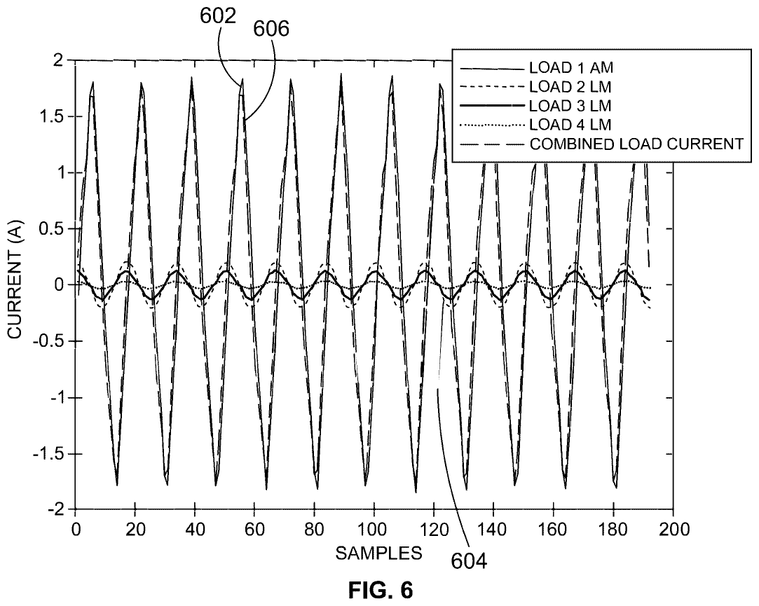

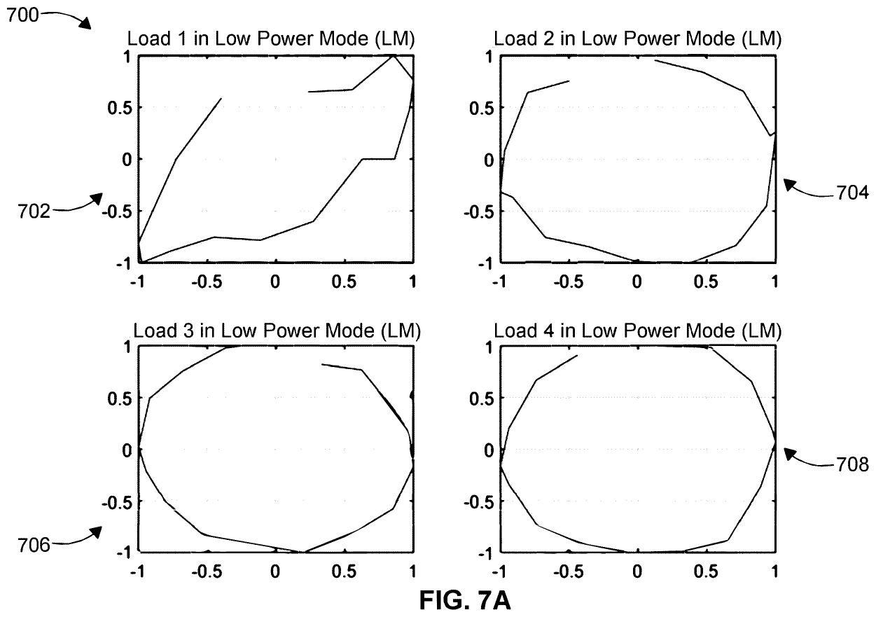

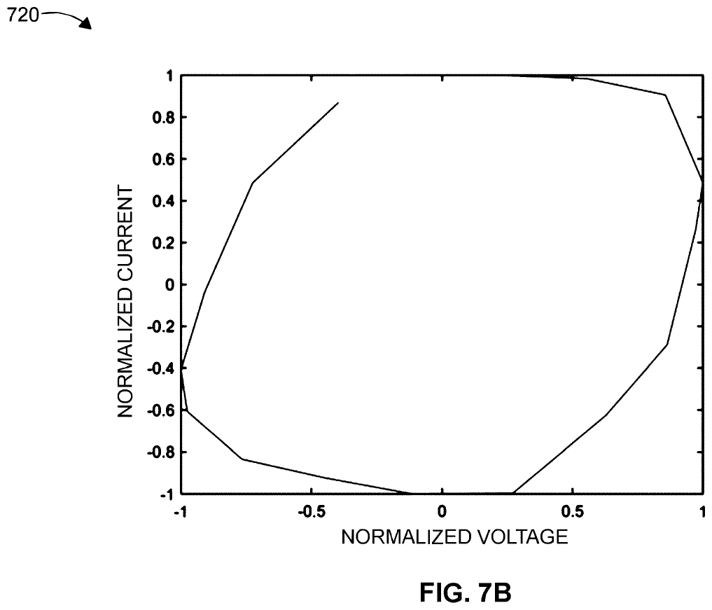

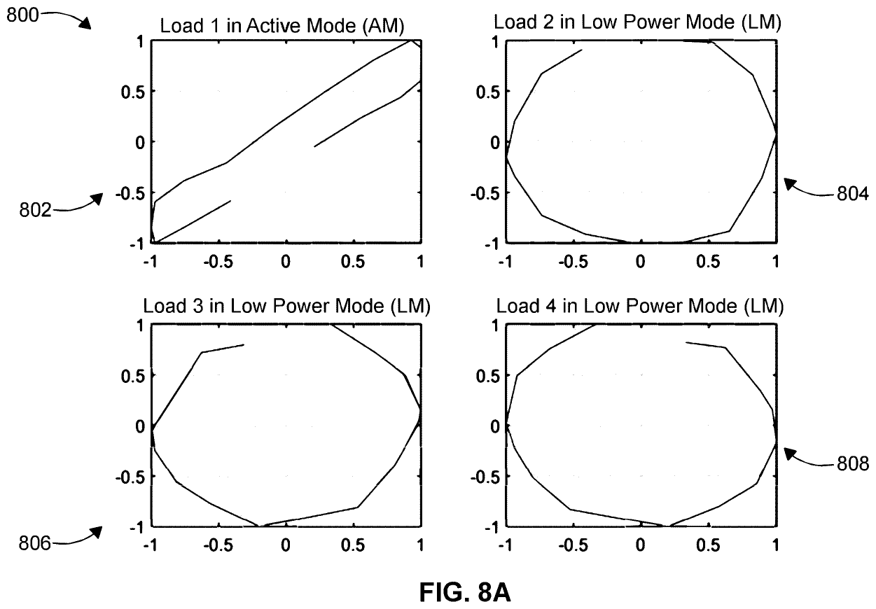

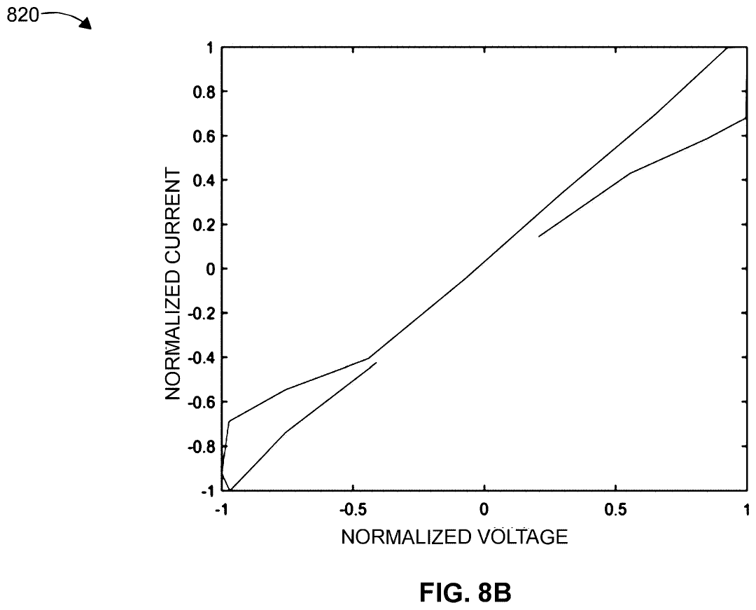

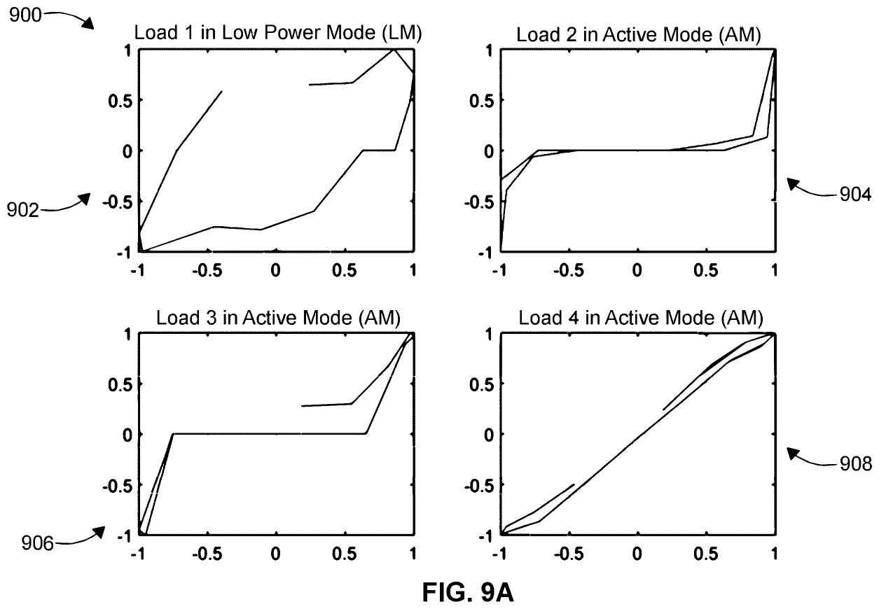

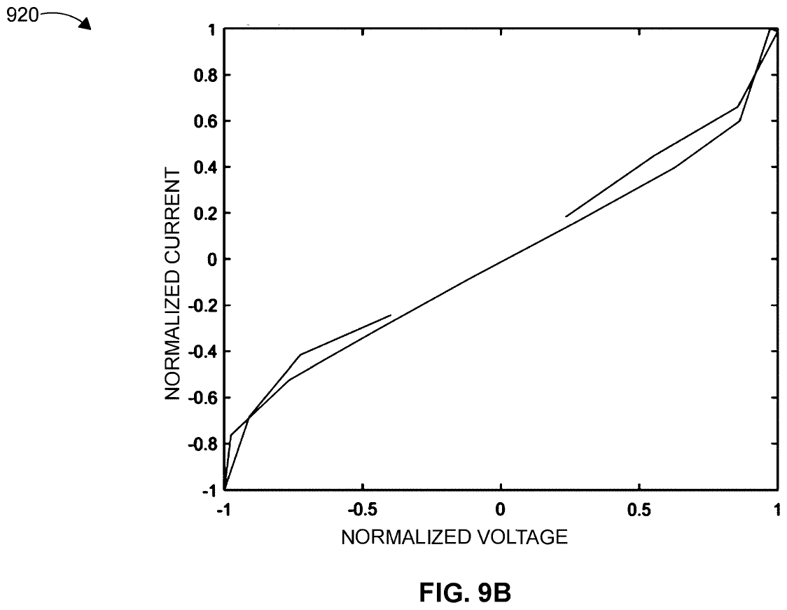

As discussed in relation to step 210 of the method 200, the load category is determined from the VI trajectory of the aggregated signal. FIGS. 7a-10b illustrate the VI trajectories for 4 loads in various operating mode combinations, to aid in disaggregating the overlapped aggregated signal. FIG. 7a shows the individual VI trajectories 700 for all 4 loads 702/704/706/708 when all loads are operating in low power mode. FIG. 7b is the combined VI trajectory 720 for the aggregated signal from the loads of FIG. 7a. As expected with all loads in low power mode, the VI trajectory 720 of the aggregated signal is comparable with the VI trajectories 700 of the individual loads 702/704/706/708. FIG. 8a shows each of the individual load VI trajectory 800 when one load is in active mode 802 and the rest are in low power mode 804/806/808. FIG. 8b is the combined VI trajectory 820 for the aggregated signal as measured when the loads are operating as in 800 of FIG. 8a, i.e. one in active mode 802 and the others in low power mode 804/806/808. It is clear that the aggregated VI trajectory 820 is dominated by the active mode load VI trajectory 802 as the shape of the VI trajectories are comparable. FIGS. 9a and 9b are representative of VI trajectories 900/920 when one load is in low power mode 902 and the rest are in active mode 904/906/908. Again, the active mode loads 904/906/908 of FIG. 9a dominate the aggregated VI trajectory 920 of FIG. 9b. FIGS. 10a and 10b are the individual VI trajectories 1000 and combined VI trajectory 1020, respectively, for the case where all loads 1002/1004/1006/1008 are operating in active mode. The combined VI trajectory 1020 in FIG. 10b has a shape that is a combination of the load VI trajectories 1000 of FIG. 10a.

Further analysis performed on various loads with different load categories revealed that the resultant load category for aggregated load is representative of the dominant load in the circuit. Thus, the VI trajectory corresponding to each load category can be used to determine the load category for the aggregated signal, as in step 210 of the method 200, and used for the analysis in steps 214 and 216. The VI trajectories for the different load categories are shown in the plots 1100 of FIG. 11. The VI trajectories are shown for load categories: Power Electronic Load without Power Factor Correction (NP) 1102; Power Electronic Load with Power Factor Correction (P) 1104; Resistive (R) 1106; Reactive (X) 1108; Complex (M) 1110; Phase Angle controlled (PAC) 1112/1114; Transformer (T) 1116; and Low Power Mode (LP) 1118. The two PAC loads 1112/1114 are presented for loads with different operating phase angles. PAC load 1112 is controlled with a phase angle >90 degrees and PAC load 1114 is controlled with a phase angle <90 degrees. Depending on the operating phase angle of a PAC device when it is in use, the VI trajectories can differ. FIG. 11 illustrates the differing VI trajectories for the PAC load 1112 and PAC load 1114. As discussed in the method 200 of FIG. 2, the load category is chosen from the evaluated VI trajectory 210 based on the plots 1100 in FIG. 11, the voltage and aggregated current waveform is normalised 212 and a sample signal of the corresponding load category is selected 214. For example, if the aggregated signal is found to be closest to the load category X, as in 1108, then a sample signal for an X category load is used for comparison. Both the aggregated signal and the sample signal are normalised before analysis commences in order to compare features of load of the same category but operating in different power ranges.

In accordance with step 216 of the method 200, the area difference between the VI trajectory of the aggregate signal and the VI trajectory of the sample signal should result in distinct area distributions as shown in plots 1200 and 1220 of FIGS. 12a and 12b. The aggregated signal comprises a signal corresponding to at least 2 or more loads, therefore when comparing the aggregated signal with an individual sample signal differences in the VI trajectories will exist. Further, these differences in VI trajectory and area distribution will be different for an aggregated signal with a low power mode present and an aggregated signal when no low power mode is present, as shown 1200 in FIGS. 12a and 1220 in FIG. 12b, respectively. The overall area distribution for when a low power mode is present 1200 is higher than that when a low power mode is absent 1220, as in FIGS. 12a and 12b. Thus, evaluating the area enclosed within the VI trajectories, i.e. plots 1200 and 1220, provides a clear differentiation in area values when an appliance is in low power mode when compared against the active mode. By evaluating the difference in area of the VI trajectories of an aggregated signal and a sample signal, it can be determined if a low power operating mode is present in the aggregated signal. As mentioned above, the area difference is one of the distinguishing features for determining the overall probability that a load is operating in low power mode from a signal of overlapping loads.

Another distinguishing feature which is analysed is the spectral coherence, as in steps 218-222 of the method 200. The spectral coherence indicates the correlation between various frequency components as well as their respective phase angles. The method 200 computes spectral coherence for a plurality of frequency components including DC (0 Hz). For the spectral coherence analysis the number of frequency components is greater than 1. In the following example, the number of frequency components is 129.

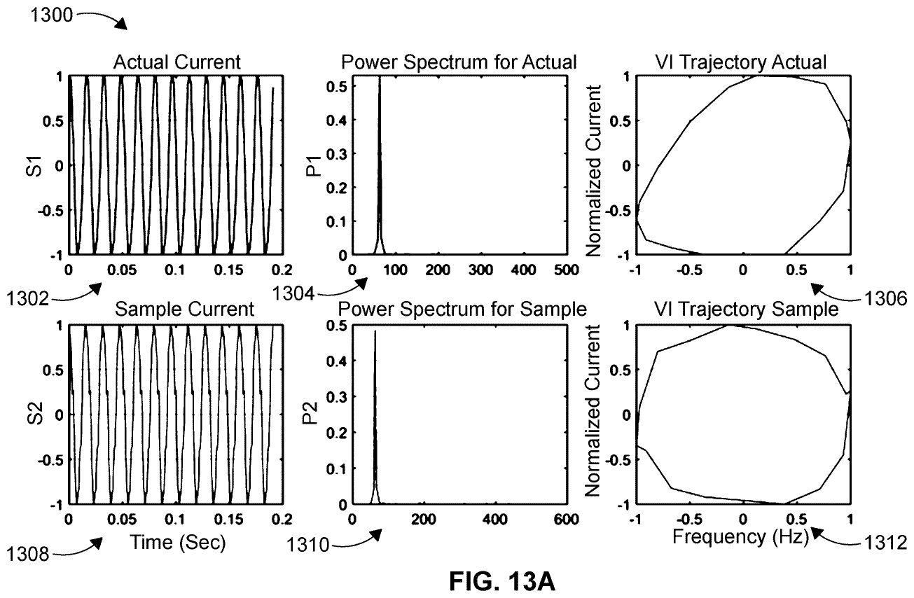

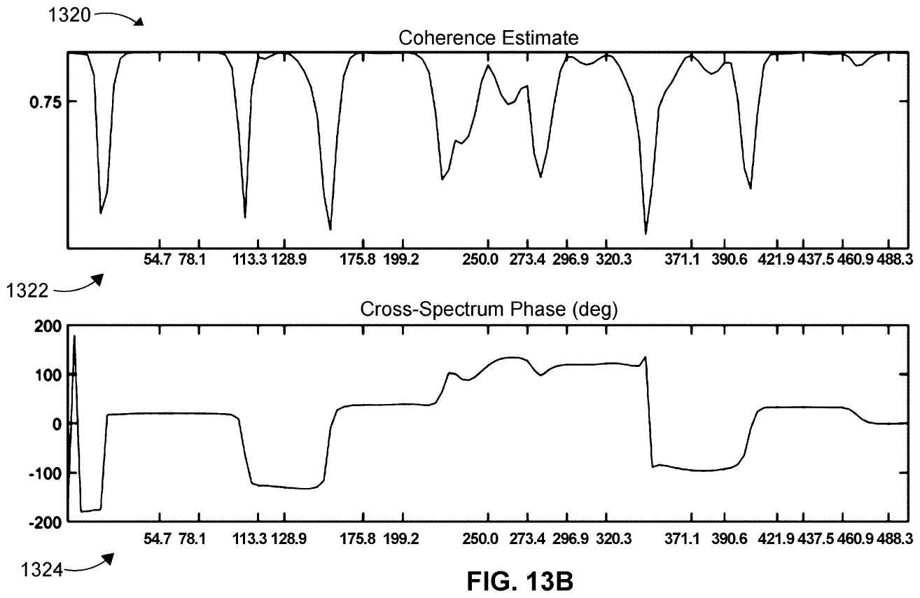

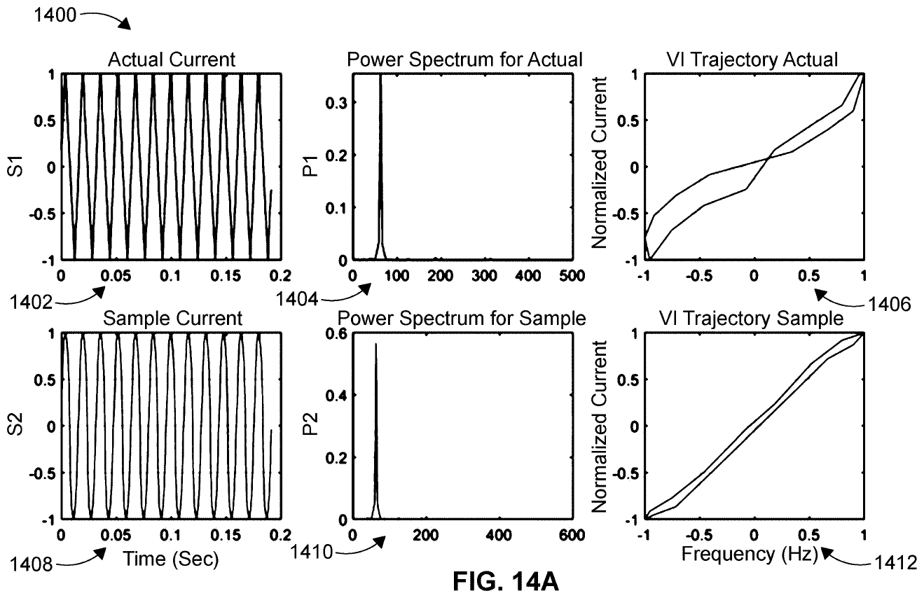

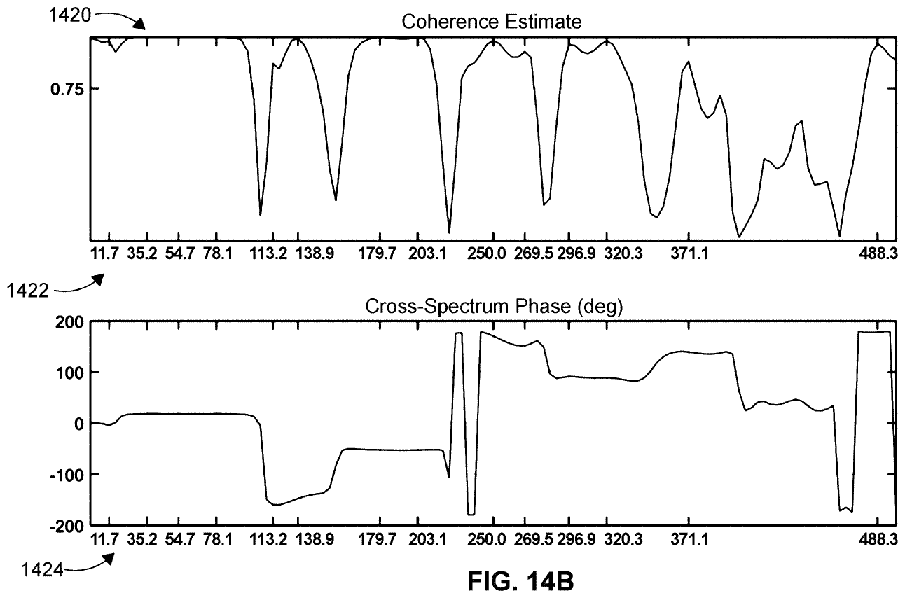

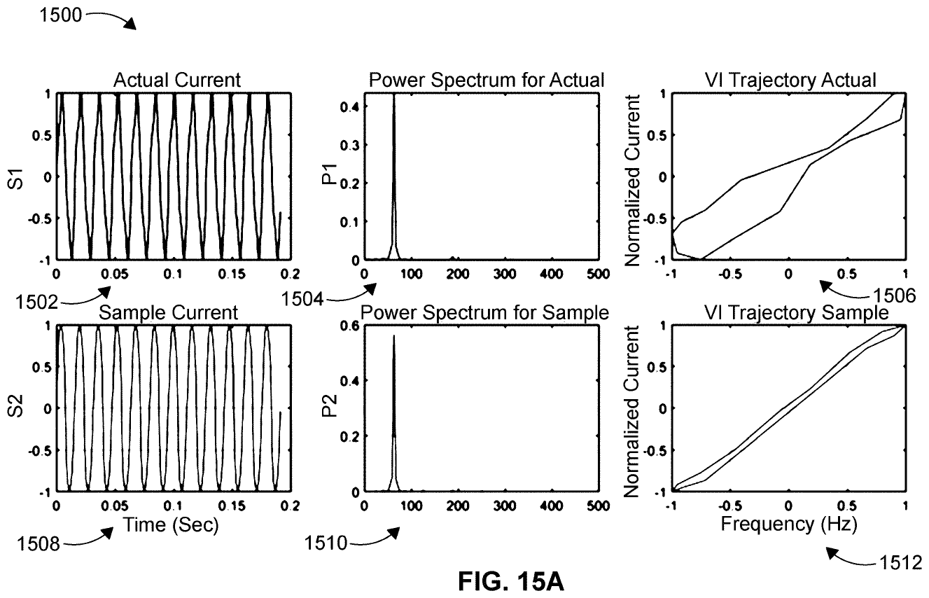

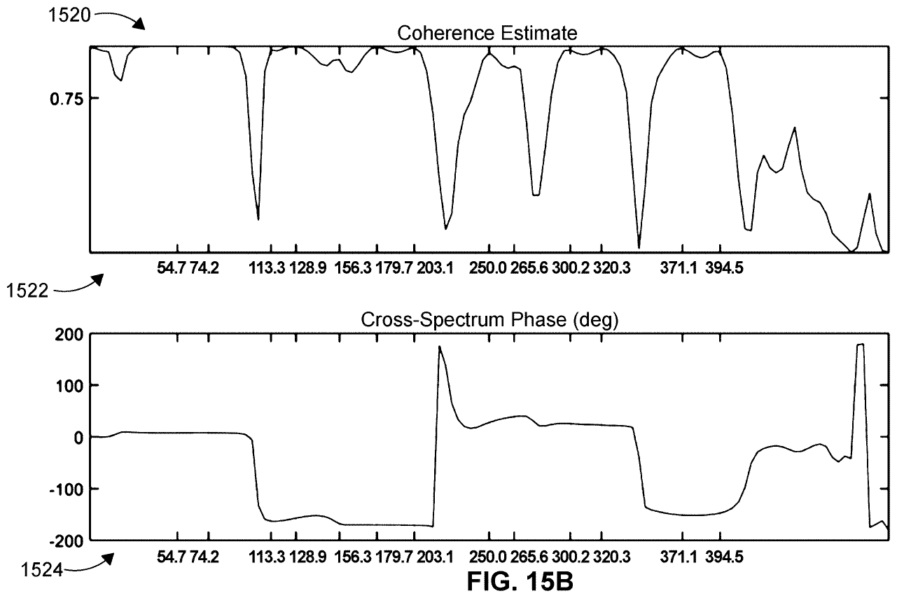

FIGS. 13a-16b show normalised plots 1300/1400/1500/1600 comparing a sample signal and aggregated signal of current (e.g. 1302 and 1308), power (e.g. 1304 and 1310) and VI trajectory (e.g. 1306 and 1312), and the corresponding coherence spectrum of current 1320/1420/1520/1620 when the loads are in a particular operating mode configuration. Plots 1300 and 1320 of FIGS. 13a and 13b are for the situation when all loads are in low power mode; plots 1400 and 1420 of FIGS. 14a and 14b are when one load is in active mode and the other loads are in low power mode; plots 1500 and 1520 of FIGS. 15a and 15b are when one load is in low power mode and the other loads are in active mode; and plots 1600 and 1620 of FIGS. 16a and 16b are when all loads are in active mode. As deduced from FIGS. 13a-16b, the spectral correlation is higher for the majority of frequency components when the load current of the aggregated signal comprises loads which are all operating in active mode. For the cases where the overlapping loads are operating in a combination of both low power mode and active mode, there are a few frequency components where correlation is decreased. Thus, for loads operating in active mode, a lower value of spectral correlation is expected as more frequency components are tightly correlated. Therefore, analysing the spectral coherence of the aggregated signal and the sample signal provides a further differentiating feature to use to detect the presence of low power modes in an aggregated signal from overlapping loads.

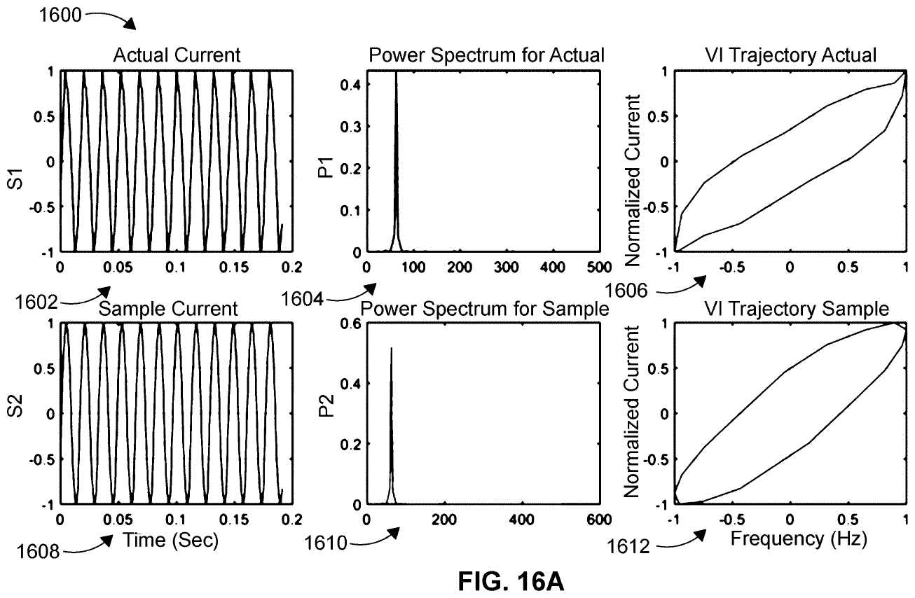

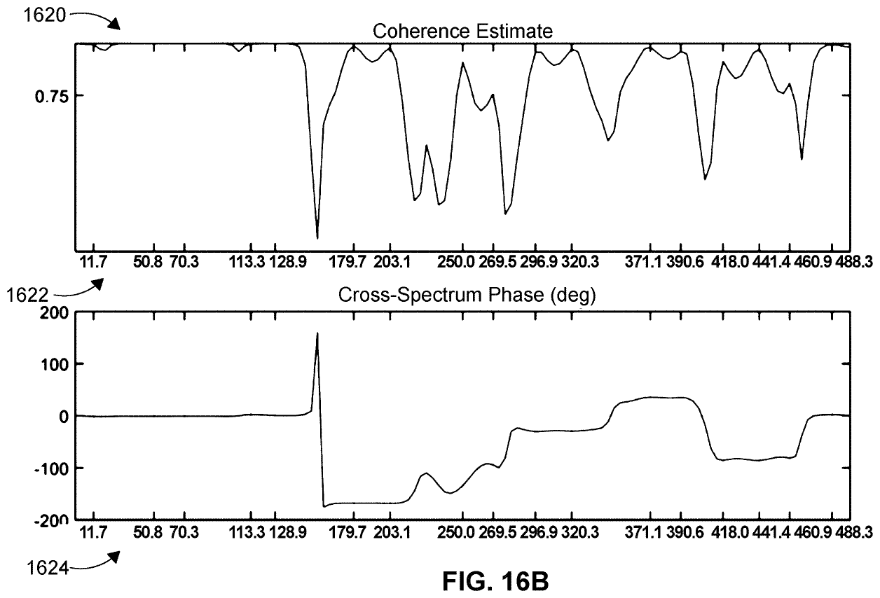

Similarly to the analysis of the area difference of the VI trajectories in 1200 and 1220 of FIGS. 12a and 12b, the distribution of correlated components for aggregated signals with and without low power present is also analysed. The frequency components are counted where the coherence value is below a threshold of 0.8, i.e. the number of correlated frequency components where the coherence value is <0.8. FIG. 17a illustrates a spectral correlation count plot 1700 when lower power, i.e. low operating mode, is present in an aggregated current of overlapping loads. FIG. 17b illustrates a spectral correlation count plot 1720 when lower power is absent in an aggregated current. In comparison, plot 1700 of FIG. 17a shows the overall number of frequency components with a coherence value below the threshold is of a higher value than that of plot 1720 of FIG. 17b. In particular, when comparing the right-hand-side of the count plots 1700 and 1720, plot 1700 has high values of probability across the higher number of correlated components, i.e. >30, whereas plot 1720 has a reduced probability for the number of correlated components values >30. Thus, for loads operating in low power mode of an aggregated signal, the overall distribution of counts of frequency components having a coherence value less than the threshold value (i.e. 0.8) is higher than when loads are operating only active mode.

A further differentiating feature used in determining if one or more loads are operating in low power mode from an aggregated signal is the phase difference at 120 Hz, as in step 224 of the method 200 in FIG. 2. FIG. 18a illustrates the count distribution of the phase difference at 120 Hz 1800 for the selected number of frequency components when lower power is present in a signal of aggregated current. FIG. 18b illustrates the count distribution of the phase difference at 120 Hz 1820 for the selected number of frequency components when lower power is absent in an aggregated current signal. It is clear that the distribution of counts when low power mode is present in the aggregated signal is of a larger number for a larger phase difference range, i.e. the number of counts at the upper end (200 deg) and lower end (−200 deg) of the phase difference is higher in plot 1800 compared to 1820. Thus, loads with low power mode present would generate overall higher phase difference range values compared to when the loads are in active mode. Therefore, evaluating the phase difference at 120 Hz aids in determining if one or more low power mode loads are present in an overlapping aggregated signal.

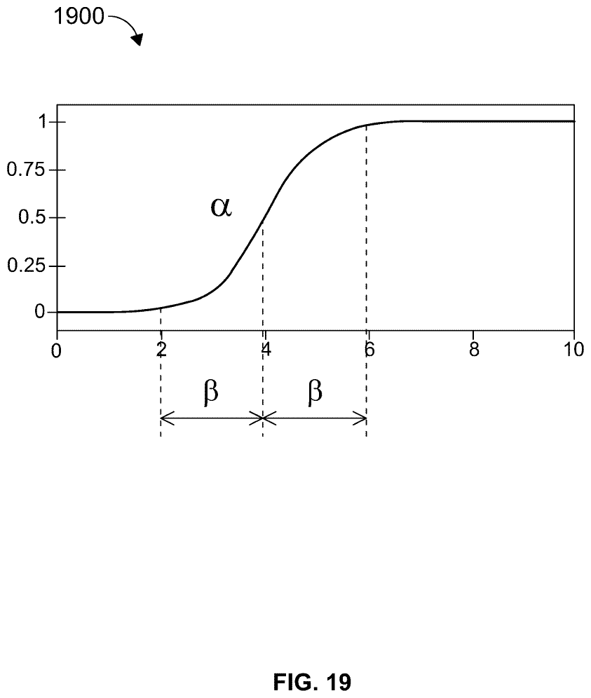

Using all the above differentiating features and their distribution plots (i.e. area difference, spectral correlation and phase difference at 120 Hz) a sigmoid membership function-based equation is used to detect the overall probability that a low power operating mode is present within an acquired overlapping aggregated signal. The sigmoid function is given by the formula:

$$f ( x ) = \frac{1}{1 + {e}^{\frac{- ( x - α )}{β}}}$$

wherein α is the centre point of the distribution and β is the width of the distribution. The sigmoid function 1900 as defined by the above equation is shown in FIG. 19, and is used for each differentiating feature. The values of α and β are derived during training and as new readings are acquired in real time, the functions of each of the corresponding features are computed and the x value determined. The resultant probability of coherence is computed as a multiplication of the outputs of each membership function as calculated using the following equation:

$$Prob = Phase 120 \times DiffArea \times SpectralCorr$$

wherein Phase120 is the membership function of the phase different at 120 Hz, DiffArea is the membership function of the VI waveform area difference, and SpectralCorr is the membership function of the spectral correlation count.

If the probability of coherence value is greater than 0.5 then it is declared that the aggregated current does not have any load, of a plurality of loads, which is operating in low power mode. If the probability of coherence value is less than 0.5 then it indicates that the aggregated current has one or more loads of a plurality of loads which are operating in low power mode. Therefore, the result of this analysis and determining if a low power mode is present in a signal of overlapping loads can be utilized to provide power management recommendations to a user. For example, the aforementioned method and system can highlight circuits where there are loads operating in low power mode, and thus can be switched off if not actively used.

It will be realised by the skilled person in the art that other distinguishing features may be evaluated to provide an increased accuracy in determining the operating mode of overlapping electric loads, for example, features from the time domain and/or frequency domain. Further, the example analyses throughout this disclosure in determining the differentiating features is based on 1 to 4 load variations. However, it will be realised by the skilled person that an increase in the number of loads on a single circuit and an increase in the number of circuits will further enhance the outcome of the method.

1. An overlapping electric loads operating mode detection method, comprising:
measuring an aggregated power signal of an electrical outlet, the aggregated power signal being an aggregated waveform;
determining an operating mode for the aggregated waveform, wherein the operating mode is determined to be one of an active mode, a lower power mode, or switched off;
on determining the operating mode is an active mode, the method further comprising:
determining a load category for the aggregated waveform;
selecting a corresponding load category signature waveform from a load category database;
evaluating spectral coherence between the aggregated waveform and the load category signature waveform;
determining an overall probability of coherence between frequency components of the aggregated waveform and the load category signature waveform; and
determining if a standby mode is present within the active mode aggregated waveform, whereby the standby mode is arranged to be detectable based on the probability of coherence value.

2. The method of claim 1, wherein measuring the aggregated waveform comprises reading the aggregated current and voltage signals of the electrical outlet.

3. The method of claim 2, wherein the reading of the aggregated current and voltage signals is performed for a minimum of 5 cycles.

4. The method of claim 1, wherein the load category of the aggregated waveform is determined to be one of a plurality of load categories, the load categories comprising:
Power Electronic Load without Power Factor Correction (NP);
Power Electronic Load with Power Factor Correction (P);
Transformer (T);
Reactive (X);
Phase Angle controlled (PAC);
Complex (M); or
Resistive (R).

5. The method of claim 1, further comprising normalising the aggregated waveform, wherein the aggregated current and voltage waveform is normalised.

6. The method of claim 1, wherein the load category signature waveforms comprise one cycle active mode normalised waveform for each load category.

7. The method of claim 1, wherein evaluating spectral coherence between the aggregated waveform and the load category signature waveform further comprises:
evaluating the difference between the aggregated waveform and the load category signature waveform based on their respective voltage/current, VI, trajectory waveforms and area enclosed in the VI trajectories.

8. The method of claim 7, wherein evaluating spectral coherence between the aggregated waveform and the load category signature waveform further comprises:
calculating the difference between the VI trajectory enclosed areas of the aggregated waveform and the load category signature waveform using root mean square error (RMSE) analysis.

9. The method of claim 8, wherein evaluating spectral coherence between the aggregated waveform and the load category signature waveform further comprises:
estimating spectral coherence between normalised current signal of aggregated waveform and normalised current signal of the load category signature waveform using Welch's averaged modified periodogram method.

10. The method of claim 9, wherein the evaluating spectral coherence between the aggregated waveform and the load category signature waveform further comprises:
recording the spectral coherence estimates for all frequency components of the compared signals.

11. The method of claim 1, further comprising evaluating the spectral correlation count between the aggregated waveform and the load category signature waveform, wherein evaluating the spectral correlation count comprises counting the number of frequency components where the coherence value is below a threshold.

12. The method of claim 11, wherein the threshold is 0.8.

13. The method of claim 1, further comprising evaluating the phase difference between the aggregated waveform and the load category signature waveform at a second harmonic frequency of 120 Hz.

14. The method of claim 1, further comprising calculating the overall probability using a sigmoid membership function for each feature, wherein the features comprise the VI waveform area difference, the spectral correlation count and the phase difference of the aggregated waveform and the load category signature waveform.

15. The method of claim 14, wherein the sigmoidal membership function is given by the equation:
$$f ( x ) = \frac{1}{1 + {e}^{\frac{- ( x - α )}{β}}}$$
wherein α is the centre point of the distribution and β is the width of the distribution.

16. The method of claim 1, wherein the overall probability of coherence is calculated using the following equation:
$$Prob = Phase 120 \times DiffArea \times SpectralCorr$$
wherein Phase120 is the membership function of the phase different at 120 Hz, DiffArea is the membership function of the VI waveform area difference, and SpectralCorr is the membership function of the spectral correlation count.

17. The method of claim 1, wherein a low power mode is determined to be present when the probability of coherence value is greater than 0.5.

18. The method of claim 1, wherein the frequency components include AC and DC.

19. The method of claim 1, wherein the number of frequency components is greater than 1.

20. An operating mode detection system of overlapping electric loads, the operating mode detection system comprising:
an electrical outlet;
an external computing component, wherein the external computing component is configured to:
measure, via the electrical outlet, an aggregated power signal, the aggregated power signal being an aggregated waveform;
determine an operating mode for the aggregated waveform, wherein the operating mode is determined to be one of an active mode, a lower power mode, or switched off;
when the operating mode is determined to be an active mode the external computing component is further configured to:
determine a load category for the aggregated waveform;
select a corresponding load category signature power signal from a load category database;
evaluate spectral coherence between the aggregated waveform and the load category signature waveform;
determine an overall probability of coherence between frequency components of the aggregated waveform and the load category signature waveform; and
determine if a standby mode is present within the active mode aggregated waveform based on the determined probability of coherence value.
